(19) United States
(12) Patent Application Publication
(10) Pub. No.: US 2024/0363160 A1
(43) Pub. Date: Oct. 31, 2024

(54) MEMORY MODULE

(71) Applicant: SONY SEMICONDUCTOR SOLUTIONS CORPORATION, KANAGAWA (JP)

(72) Inventors: YOTARO MORI, KANAGAWA (JP); RIICHI NISHINO, KANAGAWA (JP); YOSHIYUKI SHIBAHARA, KANAGAWA (JP)

(21) Appl. No.: 18/292,002

(22) PCT Filed: Mar. 16, 2022
(86) PCT No.: PCT/JP2022/011856

§ 371 Date: Jan. 25, 2024

(30) Foreign Application Priority Data
Aug. 11, 2021 (JP) 2021-131398

(51) Int. Cl. G11C 13/00; G06F 12/02

(52) U.S. Cl. CPC G11C 13/003; G06F 12/023; G11C 13/004; G11C 13/0097; G11C 13/0026; G11C 13/0028; G11C 2213/15; G11C 2213/72

(57) ABSTRACT

A memory module according to an aspect of the present disclosure includes a plurality of memory cell array units. Each of the memory cell array units includes a memory cell array including a memory cell. The memory cell is provided at each of points of intersection of a plurality of first wiring lines and a plurality of second wiring lines on a one-to-one basis. Each of the memory cell array units further includes a control unit that controls reading of data from the memory cell array and writing of data to the memory cell array. The memory cell includes a variable resistor and a selector element. The variable resistor is a resister in which one-bit information is recorded by a high or low state of a resistance value. The selector element is serially coupled to the variable resistor. The control unit performs, on the memory cell, a detection operation to detect a state of the memory cell, and thereafter, when the selector element is turned on by the detection operation, performs, on the memory cell turned on, a reset operation to cause the memory cell turned on to change from a low-resistance state to a high-resistance state.

### TECHNICAL FIELD

The present disclosure relates to a memory module.

### BACKGROUND ART

There has been known a memory module including a plurality of non-volatile rewritable memory cells. Each of the memory cells is provided with a resistive RAM (ReRAM) in which information is recorded by a state of a resistance value of the cell that is varied by application of a voltage. This memory module is provided with a plurality of memory cell arrays. Each of the memory cell arrays is of a cross-point type in which a memory cell is provided at each of points of intersection of a plurality of word lines and a plurality of bit lines (for example, see PTL 1).

### CITATION LIST

Patent Literature

PTL 1: Japanese Unexamined Patent Application Publication No. 2011-204297

### SUMMARY OF THE INVENTION

Incidentally, the above-described memory module is demanded to make a time (latency) to delete (reset) or write (set) information as short as possible. Therefore, it is desirable to provide a memory module enabling the reduction of the latency.

A memory module according to an aspect of the present disclosure includes a plurality of memory cell array units and a memory controller. The memory controller controls reading of data from the plurality of memory cell array units and writing of data to the plurality of memory cell array units. Each of the memory cell array units includes a plurality of first wiring lines, a plurality of second wiring lines, and a memory cell array including a memory cell. The memory cell is provided at each of points of intersection of the plurality of first wiring lines and the plurality of second wiring lines on a one-to-one basis. Each of the memory cell array units further includes a control unit. The control unit controls reading of data from the memory cell array and writing of data to the memory cell array on the basis of control by the memory controller. The memory cell includes a variable resistor and a selector element. The variable resistor is a resister in which one-bit information is recorded by a high or low state of a resistance value. The selector element is serially coupled to the variable resistor. The control unit performs, on the memory cell, a detection operation to detect a state of the memory cell, and thereafter, when the selector element is turned on by the detection operation, performs, on the memory cell turned on, a reset operation to cause the memory cell turned on to change from the low-resistance state to a high-resistance state.

In the memory module according to the aspect of the present disclosure, the detection operation to detect the state of the memory cell is performed on the memory cell, and thereafter, when the selector element is turned on by the detection operation, the reset operation is performed on the memory cell turned on to cause the memory cell turned on to change from the low-resistance state to the high-resistance state. This makes it possible to prevent the reset operation from being performed on a memory cell not planned to be subjected to the reset operation. Furthermore, it is possible to perform, in a period in which a set operation is performed in one memory module, a series of the detection operation and the reset operation in another memory module. It is therefore possible to omit pre-reading before the reset operation and the set operation are performed.

### BRIEF DESCRIPTION OF DRAWINGS

FIG. 1 is a diagram illustrating an example of a schematic configuration of an information processing system according to an embodiment of the present disclosure.

FIG. 2 is a diagram illustrating an example of a schematic configuration of a memory cell array unit in FIG. 1.

FIG. 3 is a diagram illustrating an example of a schematic configuration of a memory cell array in FIG. 2.

FIG. 4 is a diagram illustrating an operation example of a memory cell in FIG. 3.

FIG. 5 is a diagram illustrating an example of a selection operation on the memory cell array in FIG. 2.

FIG. 6 is a diagram illustrating a schematic configuration example of a word line decoder in FIG. 2.

FIG. 7 is a diagram illustrating an example of a voltage waveform of a memory cell in a reset operation according to a comparative example.

FIG. 8 is a diagram illustrating an example of a voltage waveform of a memory cell in the reset operation according to the comparative example.

FIG. 9 is a diagram illustrating an example of a voltage waveform of a memory cell in a reset operation according to Example.

FIG. 10 is a diagram illustrating an example of a voltage waveform of a memory cell in the reset operation according to Example.

FIG. 11 (A) is a diagram illustrating an example of an existing write operation. FIG. 11 (B) is a diagram illustrating an example of the existing write operation. FIG. 11 (C) is a diagram illustrating an example of a write operation of the embodiment.

FIG. 12 is a flowchart illustrating an example of the write operation of the embodiment.

### MODES FOR CARRYING OUT THE INVENTION

With reference to the drawings, an embodiment of the present disclosure will be described in detail below. However, the embodiment described below is merely an example, and is not intended to exclude application of various modifications and techniques not stated below. Various modifications (for example, a combination of embodiments, etc.) are able to be made to carry out the present technology without departing from its scope. Furthermore, in description of the drawings below, identical or similar parts are denoted by the same or similar reference numeral. The drawings are schematic, and are not necessarily coincident with actual dimensions and ratio, etc. Among the drawings also, some parts may differ in dimensional relationship or ratio.

### 1. EMBODIMENT

### Configuration

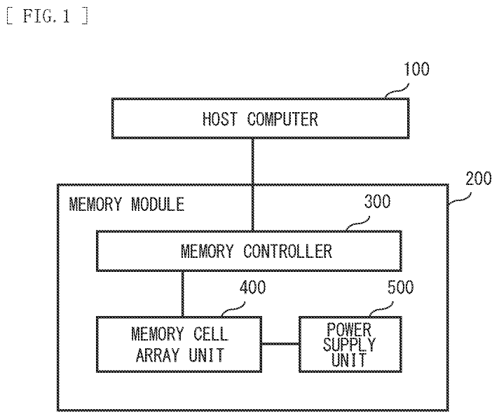

FIG. 1 illustrates an example of functional blocks of an information processing system according to an embodiment of the present disclosure. This information processing system includes a host computer 100 and a memory module 200. The memory module 200 includes a memory controller 300, a plurality of memory cell array units 400, and a power supply unit 500. (Host Computer 100)

The host computer 100 controls the memory module 200. Specifically, the host computer 100 issues a command to specify a logical address of an access destination, and supplies the command and data to the memory module 200. The host computer 100 receives data outputted from the memory module 200. The command here is for controlling the memory module 200, and includes, for example, a write command to order a data writing process or a read command to order a data reading process. Furthermore, the logical address is, in an address space defined by the host computer 100, an address assigned to each region with each access when the host computer 100 accesses the memory module 200.

### (Memory Controller 300)

The memory controller 300 controls reading/writing of data from/to the plurality of memory cell array units 400. The memory controller 300 receives the write command with a logical address specified from the host computer 100. Furthermore, in accordance with the write command, the memory controller 300 performs a data writing process. In this data writing process, the logical address is converted into a physical address, and data is written to that physical address. The physical address here is an address assigned to the plurality of memory cell array units 400 with each access when the memory controller 300 accesses the plurality of memory cell array units 400. When having received the read command with the logical address specified, the memory controller 300 converts that logical address into a physical address, and reads data from that physical address. Further, the memory controller 300 outputs the data having been read as read data to the host computer 100.

### (Power Supply Unit 500)

The power supply unit 500 supplies a desired voltage to the plurality of memory cell array units 400. For example, the power supply unit 500 supplies each of voltage control circuits 40 and 70 to be described later with a voltage used at a time of writing (at a time of setting and at a time of resetting) or at a time of reading (at a time of sensing).

### (Memory Cell Array Unit 400)

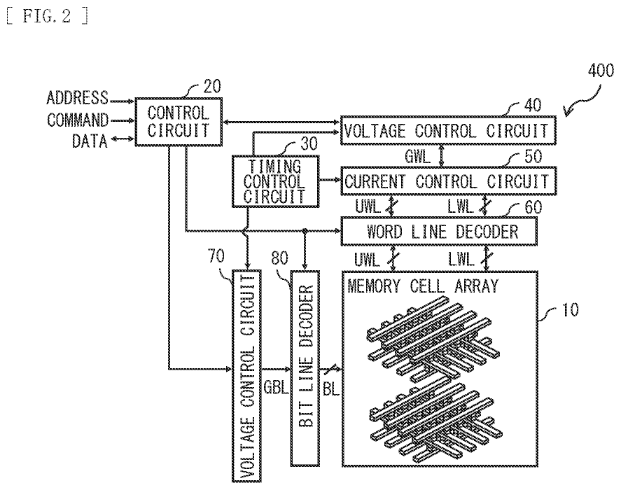

Subsequently, the memory cell array unit 400 is described. FIG. 2 illustrates an example of functional blocks of the memory cell array unit 400. The memory cell array unit 400 includes, for example, a semiconductor chip. For example, as illustrated in FIG. 2, the memory cell array unit 400 includes a plurality of word lines WL, a plurality of bit lines BL, and a memory cell array 10.

### (Memory Cell Array 10)

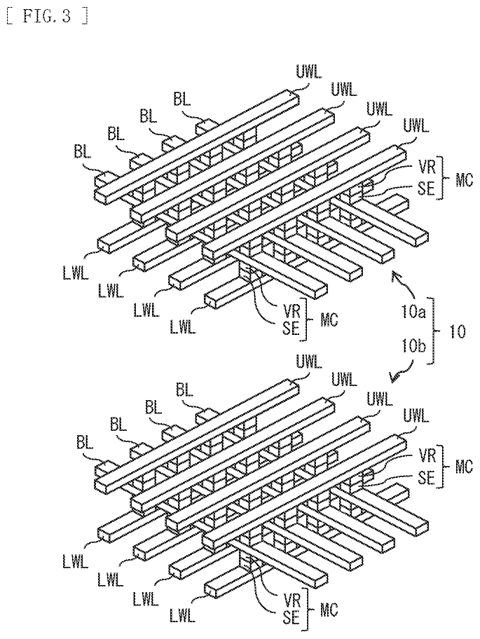

The memory cell array 10 includes, for example, two layers of memory cell arrays 10a and 10b as illustrated in FIG. 3. For example, as illustrated in FIG. 3, the memory cell arrays 10a and 10b each include 1-bit memory cells MC at respective points of intersection of upper word lines UWL and bit lines BL and respective points of intersection of lower word lines LWL and the bit lines BL. The memory cell MC is a writable non-volatile memory. The memory cell MC has a serial structure of a variable resistor VR (Variable Resistor) and a selector element SE (Selector Element). The variable resistor VR is a resistor in which 1-bit information is recorded in accordance with a high or low state of a resistance value. The selector element SE has a bidirectional diode characteristic. In the following, the upper word lines UWL and the lower word lines LWL are collectively referred to as word lines WL where appropriate.

In the memory cell array 10, it is possible to write data to a memory cell MC specified by an input of an address from the outside. Furthermore, it is possible to read data stored in the memory cell MC specified by the input of the address. The data value stored in the memory cell MC is distinguished by the resistance state of the variable resistor VR. For example, it is distinguished as “0” if it is in a high-resistance state, and is distinguished as “1” if it is in a low-resistance state.

FIG. 4 illustrates an I-V characteristic of the memory cell MC. It is assumed that a voltage at both ends of the memory cell MC is swept from 0 V when the variable resistor VR is in a low-resistance state (LRS). At this time, in a case where the voltage at the both ends of the memory cell MC drops at 4 V, and a current suddenly flows into the memory cell MC, this phenomenon is called a snap, and a snap voltage Vsnap_LRS is 4 V. A snap voltage Vsnap_HRS at a time when the variable resistor VR is in a high-resistance state (HRS) is higher than the snap voltage Vsnap_LRS, and is, for example, 6 V. When 5 V is applied to the memory cell MC of which the state is desired to be known, the memory cell MC is snapped when the variable resistor VR is in the low-resistance state (LRS), and the memory cell MC is not snapped when the variable resistor VR is in the high-resistance state (HRS). Therefore, by recognizing the presence or absence of a snap, it is possible to perform reading of data from the memory cell MC. When the variable resistor VR is in the high-resistance state (HRS), the memory cell MC is snapped, and the variable resistor VR is put into a molten state and is then cooled. This causes the variable resistor VR to change to the low-resistance state (LRS). When the variable resistor VR is in the low-resistance state (LRS), a high voltage is applied to the memory cell MC, and the memory cell MC is snapped. This causes the variable resistor VR to change to the high-resistance state (HRS). By combining the above-described reading of data and the resistance change of the variable resistor VR, it is possible to perform writing of data to the memory cell MC.

In a case of performing reading of data from the memory cell MC, for example, after the word lines WL are charged to −2.5 V, a control circuit 20 applies +2.5 V to the bit lines BL. As a result, when the variable resistors VR of the memory cells MC located at the points of intersection of the word lines WL and the bit lines BL are in the low-resistance state (LRS), the memory cells MC are snapped, and the parasitic capacitance of the word lines WL is discharged, and the potential of the word lines WL increases to about 0 V. When the variable resistors VR of the memory cells MC located at the points of intersection of the word lines WL and the bit lines BL are in the high-resistance state (HRS), the memory cells MC are not snapped, and only a slight leakage current flows through the word line WL, and the potential of the word line WL is kept at about −2 V. At this time, for example, using a sense amplifier, the control circuit 20 compares a voltage of the word line WL with a reference voltage Vref (for example, about −1 V), and determines whether the variable resistor VR is in the low-resistance state (LRS) or the high-resistance state (HRS). For example, the control circuit 20 generates logic 1 in a case where the variable resistor VR is in the low-resistance state (LRS), or generates logic 0 in a case where the variable resistor VR is in the high-resistance state (HRS), to thereby generate read data. For example, the control circuit 20 outputs the generated read data to the memory controller 300.

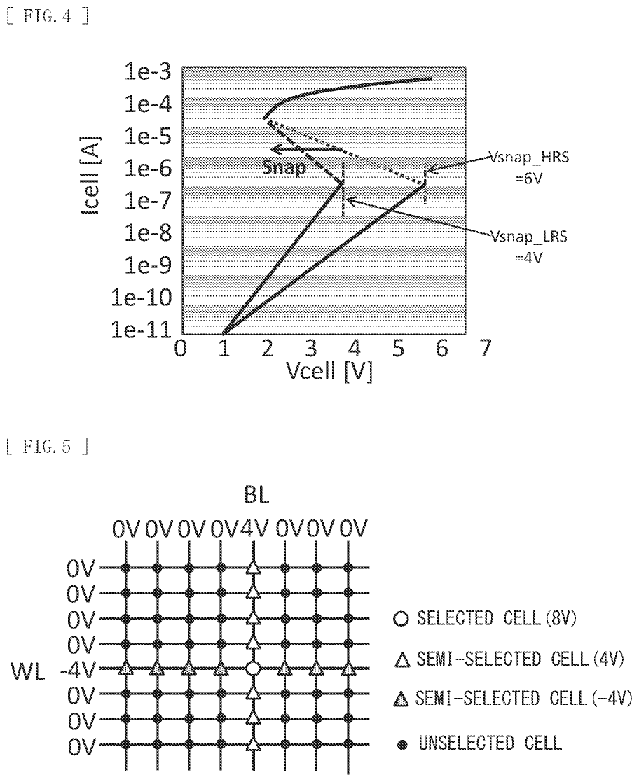

In a case of performing the writing (setting) of data to the memory cell MC in which the variable resistor VR is in the high-resistance state (HRS), for example, after charging the word line WL to Vneg1 (for example, −4 V), the control circuit 20 applies Vset (for example, +4 V) to the bit line BL (see FIG. 5). As a result, the memory cell MC located at the point of intersection of the word line WL and the bit line BL is snapped, and the variable resistor VR goes into a molten state and then is cooled. This causes the memory cell MC to change from the high-resistance state (HRS) to the low-resistance state (LRS). The memory cell MC is set in this way.

In a case of performing the writing (resetting) of data to the memory cell MC in which the variable resistor VR is in the low-resistance state (LRS), for example, after charging the lower word line LWL to Vneg1 (for example, −4 V), the control circuit 20 applies Vrst (for example, +4 V) to the bit line BL (see FIG. 5). As a result, the memory cell MC located at the point of intersection of the lower word line LWL and the bit line BL is snapped, and the variable resistor VR changes from the low-resistance state (LRS) to the high-resistance state (HRS). The memory cell MC is reset in this way.

In the above-described set operation and reset operation, for example, Vcom (for example, 0 V) is applied to the bit lines BL (unselected bit lines BL) different from the bit line BL (the selected bit line BL) to which Vset and Vrst (for example, +4 V) have been applied. Furthermore, for example, Vcom (for example, 0 V) is applied to the word lines WL (unselected word lines WL) different from the word line WL (the selected word line WL) to which Vnegl (for example, −4 V) has been applied. Here, it is important not to apply a voltage Vth (=Vsnap_LRS), which allows the selector element SE to be turned on, to the memory cells MC located at the points of intersection of the selected bit line BL and the unselected word lines WL (semi-selected cells

MC indicated by triangles in FIG. 5). Furthermore, it is important not to apply the voltage Vth, which allows the selector element SE to be turned on, to the memory cells MC located at the points of intersection of the unselected bit lines BL and the selected word line WL (semi-selected cells MC indicated by dot-patterned triangles in FIG. 5). One reason for this is that in the semi-selected cell, in a case where the selector element SE is turned on and the variable resistor VR is in the low-resistance state (LRS), a current flowing into the semi-selected cell not only makes the memory cell MC desired to be selected unselectable but also creates a possibility that the state of the semi-selected cell may be corrupted. In the present embodiment, while preventing such corruption, in terms of expanding the range of choices for a memory material, a write operation (the set operation and the reset operation) that allows the application of a voltage as high as possible is performed.

The memory cell array unit 400 further includes, for example, as illustrated in FIG. 2, the control circuit 20, a timing control circuit 30, the voltage control circuit 40, a current control circuit 50, a word line decoder 60, the voltage control circuit 70, and a bit line decoder 80. The control circuit 20, the timing control circuit 30, the voltage control circuit 40, the current control circuit 50, the word line decoder 60, the voltage control circuit 70, and the bit line decoder 80 control the reading/writing of data from/to the memory cell array 10 on the basis of control by the memory controller 300.

For example, the control circuit 20 exchanges an address, a command (such as a write command or a read command), and data (such as write data or read data) with the memory controller 300. For example, in accordance with the command and the address, the control circuit 20 controls the voltage control circuits 40 and 70, the word line decoder 60, and the bit line decoder 80. The timing control circuit 30 controls a timing for the voltage control circuits 40 and 70 and the current control circuit 50 to output a voltage used for the writing/reading of data to/from the memory cell array 10.

When subjected to writing control by the control circuit 20 or the timing control circuit 30, the voltage control circuit 40 applies a voltage necessary for a write operation to a global word line GWL. When subjected to reading control by the control circuit 20 or the timing control circuit 30, the voltage control circuit 40 applies a voltage necessary for a read operation to the global word line GWL, and reads read data through the global word line GWL.

The current control circuit 50 controls a current that flows through the word lines WL. When writing of data is performed, the current control circuit 50 controls a current caused to flow through the word lines WL by the voltage control circuit 40 in such a manner that the current caused to flow through the word lines WL are limited to a predetermined limited current value. The current control circuit 50 includes, for example, two NMOS transistors and a constant current source. The two NMOS transistors have respective gate terminals coupled to each other. In the current control circuit 50, one of the NMOS transistors is coupled to the word lines WL, and the other NMOS transistor is coupled to the constant current source. The two NMOS transistors and the constant current source constitute a current mirror circuit. In a case where the NMOS transistor coupled to the word lines WL operates in a saturated state, the predetermined limited current flows through the word lines WL.

The word line decoder 60 selects the word line WL on the basis of word line address information given from the control circuit 20. The word line decoder 60 outputs a predetermined voltage necessary for a write or read operation to the selected word line WL. To the word lines WL (unselected word lines WL) other than the selected word line WL, the word line decoder 60 outputs a predetermined voltage that does not allow the selector element SE to be turned on.

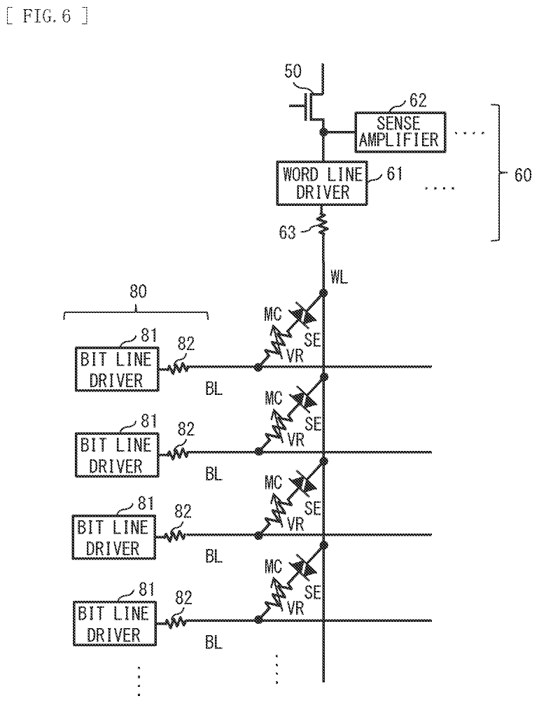

FIG. 6 illustrates a circuit configuration example of the current control circuit 50, the word line decoder 60, and the bit line decoder 80. The current control circuit 50 includes a selector element having a current limiting function. The word line decoder 60 includes the selector element having the current limiting function (the current control circuit 50) as an element that selects the word line WL, a word line driver 61, and a sense amplifier 62. The word line driver 61 outputs a predetermined voltage necessary for the write or read operation to the selected word line WL. The word line driver 61 further includes a transistor for causing a voltage of the unselected word lines WL of the memory cell MC to be a predetermined voltage. The word line decoder 60 further includes an internal resistance 63. The current outputted from the word line decoder 60 flows into the internal resistance 63, which causes a voltage drop (an IR drop).

On the basis of a control signal from the control circuit 20, the sense amplifier 62 compares the voltage of the word line WL with the reference voltage Vref (for example, about −1 V), and determines whether the variable resistor VR is in the low-resistance state (LRS) or the high-resistance state (HRS). The sense amplifier 62 generates logic 1 in a case where the variable resistor VR is in the low-resistance state (LRS), or generates logic 0 in a case where the variable resistor VR is in the high-resistance state (HRS), to thereby generates read data. The sense amplifier 62 outputs the generated read data to the control circuit 20.

The bit line decoder 80 includes a bit line driver 81 and an internal resistance 82. The bit line driver 81 outputs a predetermined voltage necessary for the write or read operation to the selected bit line BL. The bit line driver 81 further includes a transistor for causing a voltage of the unselected bit lines BL of the memory cell MC to be a predetermined voltage. The current outputted from the bit line decoder 80 flows into the internal resistance 82, which causes an IR drop.

When subjected to the writing control by the control circuit 20, the voltage control circuit 70 applies a voltage necessary for the write operation to a global bit line GBL. When subjected to the reading control by the control circuit 20, the voltage control circuit 40 outputs a voltage necessary for the read operation to the global bit line GBL. The bit line decoder 80 selects the bit line BL on the basis of bit line address information given from the control circuit 20. To the bit lines BL (unselected bit lines BL) other than the selected bit line BL, the bit line decoder 80 outputs a predetermined voltage that does not allow the selector element SE to be turned on.

### [Operation]

Subsequently, the reset operation of the memory cell array unit 400 according to the present embodiment is described as compared with that in a comparative example.

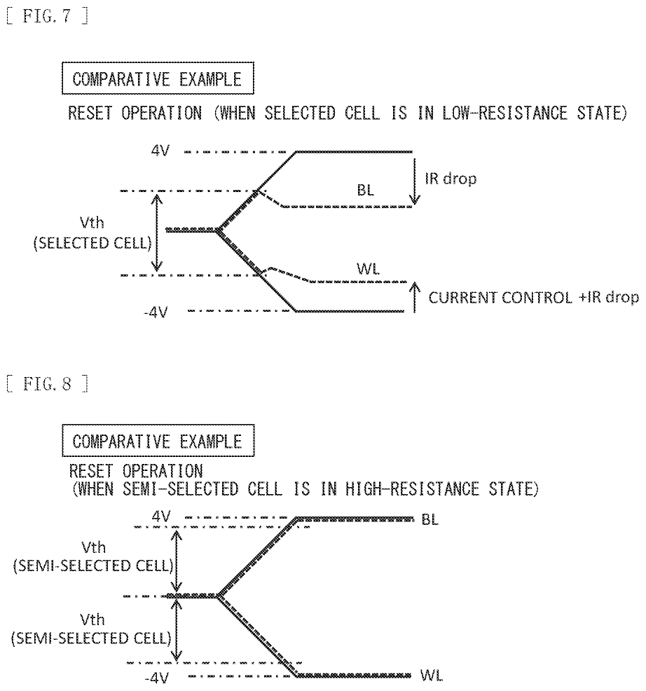

FIG. 7 illustrates an example of a voltage waveform of a selected cell in a reset operation according to the comparative example. FIG. 8 illustrates an example of a voltage waveform of a semi-selected cell in the reset operation according to the comparative example. FIG. 7 illustrates an example of the voltage waveform at a time when the selected cell is in the low-resistance state. FIG. 8 illustrates an example of the voltage waveform at a time when the semi-selected cell is in the high-resistance state. In FIG. 7, a solid line indicates a set voltage to a circuit that applies a voltage to the selected cell, and dashed lines indicate respective voltages of the word line WL and the bit line BL that are coupled to the selected cell. In FIG. 8, a solid line indicates a set voltage to a circuit that applies a voltage to the semi-selected cell, and dashed lines indicate respective voltages of the word line WL and the bit line BL that are coupled to the semi-selected cell. In the following, a circuit corresponding to the control circuit 20 in the comparative example is referred to as a control circuit 20′.

### (When Selected Cell Is in Low-Resistance State, FIG. 7)

Before the reset operation, the control circuit 20′ drives all the word lines WL and the bit lines BL to a common voltage Vcom (for example, 0 V) through the word line decoder 60 and the bit line decoder 80. Upon the start of the reset operation, the control circuit 20′ drives the selected word line WL to a predetermined voltage Vnegl (for example, −4 V) through the word line decoder 60, and further drives the selected bit line BL to a predetermined voltage Vrst (for example, +4 V) through the bit line decoder 80.

When the voltage applied to the selector element SE in the selected cell increases, a current corresponding to the characteristic of the selector element SE flows into the selected cell. At this time, when the voltage applied to the selected cell gradually increases, and a voltage exceeding the on-voltage Vth of the selector element SE is applied to the selector element SE in the selected cell, the selector element SE is turned on. Thereafter, when a voltage exceeding the snap voltage Vsnap_LRS is applied to the variable resistor VR in the low-resistance state in the selected cell, the memory cell MC is snapped, and a large current starts flowing into the selected cell. At this time, due to current limitation by the current control circuit 50, the current flowing into the selected cell is limited. Furthermore, an IR drop is caused by the current flowing through the word line WL or the bit line BL coupled to the selected cell. As a result, the voltage of the word line WL becomes a voltage less than the voltage Vneg1 (for example, −4 V), and the voltage of the bit line BL becomes a voltage less than the voltage Vrst (for example, +4 V).

### (When Semi-Selected Cell Is in High-Resistance State, FIG. 8)

Before the reset operation, the control circuit 20′ drives all the word lines WL and the bit lines BL to the common voltage Vcom (for example, 0 V) through the word line decoder 60 and the bit line decoder 80. Upon the start of the reset operation, the control circuit 20′ drives the selected word line WL to the predetermined voltage Vnegl (for example, −4 V) through the word line decoder 60, or drives the selected bit line BL to the predetermined voltage Vrst (for example, +4 V) through the bit line decoder 80. Here, the memory cells MC coupled to the selected bit line BL and the unselected word lines WL and the memory cells MC coupled to the unselected bit lines BL and the selected word line WL each correspond to the above-described semi-selected cell. When the voltage applied to the selector element SE in the semi-selected cell increases, a current corresponding to the characteristic of the selector element SE flows into the semi-selected cell. At this time, when the voltage applied to the semi-selected cell gradually increases, and a voltage exceeding the on-voltage Vth of the selector element SE is applied to the selector element SE in the semi-selected cell, the selector element SE is turned on. However, a voltage exceeding the snap voltage Vsnap_HRS is not applied to the variable resistor VR in the high-resistance state in the semi-selected cell; therefore, the memory cell MC is not snapped and is maintained in the high-resistance state.

Incidentally, it is assumed that when the semi-selected cell is in the low-resistance state, the control circuit 20′ drives the selected word line WL to the predetermined voltage Vnegl (for example, −4 V) through the word line decoder 60, or drives the selected bit line BL to the predetermined voltage Vrst (for example, +4 V) through the bit line decoder 80. At this time, in the semi-selected cell, the selector element SE is turned on, and the memory cell MC is snapped, and a large current flows into the semi-selected cell. As a result, in a case where the semi-selected cell changes from the low-resistance state to the high-resistance state, the state (data) of the semi-selected cell is corrupted. As described above, the reset operation according to the comparative example has an issue that there is a possibility that the state (data) of the semi-selected cell may be corrupted.

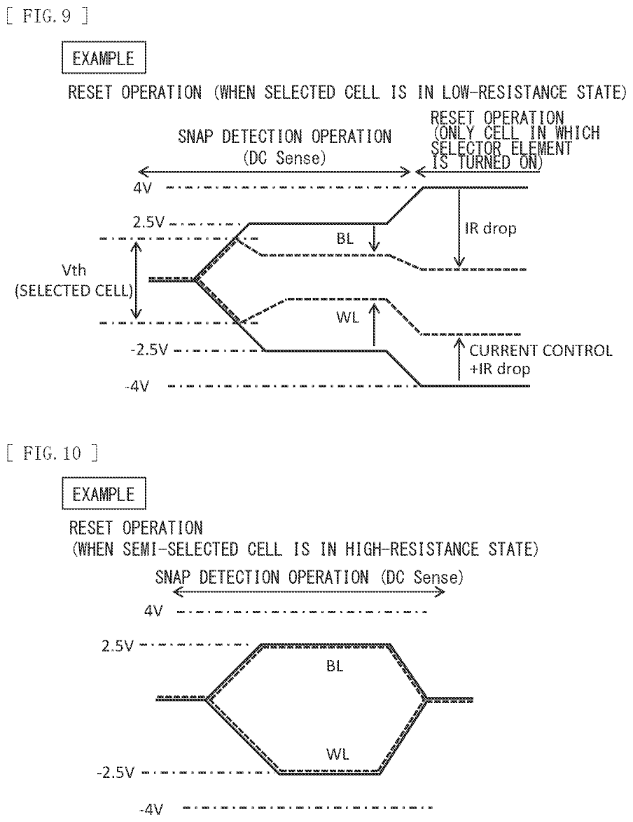

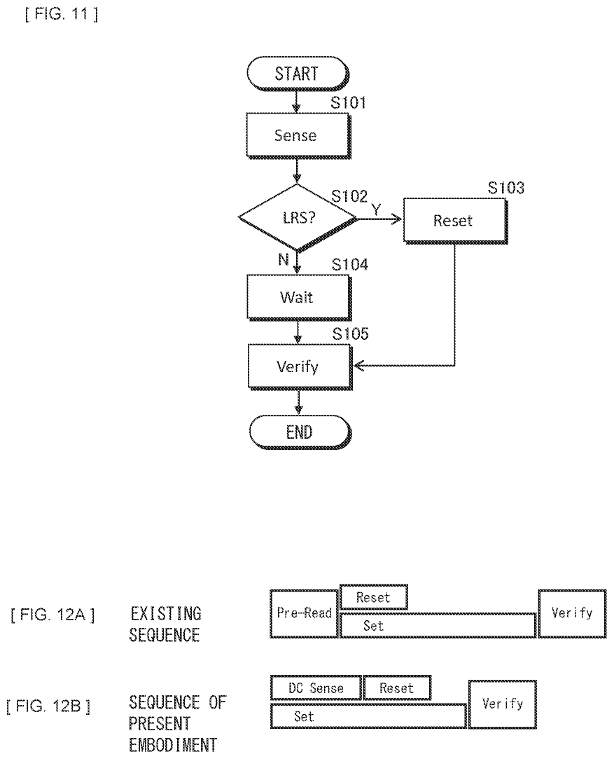

FIG. 9 illustrates an example of a voltage waveform of a selected cell in the reset operation according to the present embodiment. FIG. 10 illustrates an example of a voltage waveform of a semi-selected cell in the reset operation according to the present embodiment. FIG. 11 illustrates an example of a procedure of the reset operation according to the present embodiment. FIG. 9 illustrates an example of a voltage waveform when the selected cell is in the low-resistance state. FIG. 10 illustrates an example of a voltage waveform when the semi-selected cell is in the high-resistance state. In FIG. 9, a solid line indicates a set voltage to a circuit that applies a voltage to the selected cell, and dashed lines indicate respective voltages of the word line WL and the bit line BL that are coupled to the selected cell. In FIG. 10, a solid line indicates a set voltage to a circuit that applies a voltage to the semi-selected cell, and dashed lines indicate respective voltages of the word line WL and the bit line BL that are coupled to the semi-selected cell.

### (When Selected Cell Is in Low-Resistance State, FIG. 9)

Before the reset operation, the control circuit 20 drives all the word lines WL and the bit lines BL to the common voltage Vcom (for example, 0 V) through the word line decoder 60 and the bit line decoder 80. Upon the start of the reset operation, the control circuit 20 performs a Snap detection operation on the memory cell MC to detect the state of the memory cell MC. Specifically, the control circuit 20 drives the selected word line WL to a predetermined voltage Vneg2 (for example, −2.5 V) through the word line decoder 60, and further drives the selected bit line BL to a predetermined voltage Vread (for example, +2.5 V) through the bit line decoder 80. Here, |Vneg2−Vread| is a voltage that does not allow the selector element SE to be turned on when the variable resistor VR is in the high-resistance state. It is to be noted that the control circuit 20 performs the Snap detection operation on, of the plurality of memory cells MC, multiple memory cells MC coupled to the word line WL or the bit line BL in common with the memory cell turned on.

Thereafter, the control circuit 20 performs the Snap detection operation on the memory cell MC to detect the state of the memory cell MC. Specifically, when the voltage applied to the selector element SE in the selected cell increases, a current corresponding to the characteristic of the selector element SE flows into the selected cell. At this time, when the voltage applied to the selected cell gradually increases, and a voltage exceeding the on-voltage Vth of the selector element SE is applied to the selector element SE in the selected cell, the selector element SE is turned on. Thereafter, when a voltage exceeding the snap voltage Vsnap_LRS is applied to the variable resistor VR in the low-resistance state in the selected cell, the memory cell MC is snapped, and a large current starts flowing into the selected cell. At this time, due to the current limitation by the current control circuit 50, the current flowing into the selected cell is limited. Furthermore, an IR drop is caused by the current flowing through the word line WL or the bit line BL coupled to the selected cell. As a result, the voltage of the word line WL becomes a voltage less than the voltage Vneg2 (for example, −2.5 V), and the voltage of the bit line BL becomes a voltage less than the voltage Vread (for example, +2.5 V).

At this time, for example, using the sense amplifier 62, the control circuit 20 detects the voltage of the word line WL (step S101). The control circuit 20 compares the detected voltage of the word line WL with the reference voltage Vref (for example, about −1 V), and determines whether the variable resistor VR is in the low-resistance state (LRS) or the high-resistance state (HRS) (step S102). For example, the control circuit 20 generates logic 1 in a case where the variable resistor VR is in the low-resistance state (LRS), or generates logic 0 in a case where the variable resistor VR is in the high-resistance state (HRS), to thereby generate read data. For example, the control circuit 20 outputs the generated read data to the memory controller 300.

For example, when an absolute value of the voltage of the word line WL is smaller than an absolute value of the reference voltage Vref (for example, about −1 V) as illustrated in FIG. 9, the control circuit 20 determines that the variable resistor VR is in the low-resistance state (LRS). In a case where it has been determined that the variable resistor VR is in the low-resistance state (LRS), the control circuit 20 performs the reset operation (step S103). In contrast, when the absolute value of the voltage of the word line WL is greater than or equal to the absolute value of the reference voltage Vref (for example, about −1 V), the reset operation is not performed (step S104).

When the selector element SE is turned on by the detection operation, the control circuit 20 performs the reset operation to change the memory cell MC turned on from the low-resistance state to the high-resistance state. Specifically, the control circuit 20 performs the reset operation as follows. The control circuit 20 drives the selected word line WL to the predetermined voltage Vneg1 (for example, −4 V) through the word line decoder 60, and further drives the selected bit line BL to the predetermined voltage Vrst (for example, +4 V) through the bit line decoder 80. |Vneg1−Vrst| is a voltage that allows the memory cell turned on to change from the low-resistance state to the high-resistance state in the reset operation.

At this time, when a transition from the detection operation to the reset operation is made, the control circuit 20 causes the voltage outputted to the selected word line WL to be continuously (i.e., gently and not rectangularly) changed from Vneg2 (for example, −2.5 V) to Vneg1 (for example, −4 V). When the transition from the detection operation to the reset operation is made, the control circuit 20 further causes the voltage outputted to the selected bit line BL to be continuously (i.e., gently and not rectangularly) changed from Vread (for example, +2.5 V) to Vrst (for example, +4 V). This makes it possible to prevent the selector element SE to be momentarily turned off in the course of making a transition from the Snap detection operation to the reset operation, and makes it possible to prevent the state of the selected cell from being changed.

When a voltage exceeding the snap voltage Vsnap_LRS is applied to the variable resistor VR in the low-resistance state in the selected cell, the memory cell MC is snapped, and a large current starts flowing into the selected cell. At this time, due to the current limitation by the current control circuit 50, the current flowing into the selected cell is limited. Furthermore, an IR drop is caused by the current flowing through the word line WL or the bit line BL coupled to the selected cell. As a result, the voltage of the word line WL becomes a voltage less than the voltage Vneg1 (for example, −4 V), and the voltage of the bit line BL becomes a voltage less than the voltage Vrst (for example, +4 V). As a result, the variable resistor VR changes from the low-resistance state (LRS) to the high-resistance state (HRS). In this way, the reset operation is completed. Thereafter, the control circuit 20 may verify whether the reset has been certainly performed (the read operation) on an as-needed basis (step S105).

### (When Semi-Selected Cell Is in High-Resistance State, FIG. 10)

Before the reset operation, the control circuit 20 drives all the word lines WL and the bit lines BL to the common voltage Vcom (for example, 0 V) through the word line decoder 60 and the bit line decoder 80. Upon the start of the reset operation, the control circuit 20 drives the selected word line WL to the predetermined voltage Vneg2 (for example, −2.5 V) through the word line decoder 60, or drives the selected bit line BL to the predetermined voltage Vread (for example, +2.5 V) through the bit line decoder 80. Here, the memory cells MC coupled to the selected bit line BL and the unselected word lines WL and the memory cells MC coupled to the unselected bit lines BL and the selected word line WL correspond to the above-described semi-selected cell.

When the voltage applied to the selector element SE in the semi-selected cell increases, a current corresponding to the characteristic of the selector element SE flows into the semi-selected cell. At this time, the voltage applied to the semi-selected cell gradually increases; however, a voltage exceeding the on-voltage Vth of the selector element SE is not applied to the selector element SE in the semi-selected cell. Thus, the selector element SE is not turned on and remains off. As a result, the voltage of the word line WL becomes the voltage Vneg2 (for example, −2.5 V), and the voltage of the bit line BL becomes the voltage Vread (for example, +2.5 V).

At this time, for example, using the sense amplifier 62, the control circuit 20 detects the voltage of the word line WL (step S101). The control circuit 20 compares the detected voltage of the word line WL with the reference voltage Vref (for example, about −1 V), and determines whether the variable resistor VR is in the low-resistance state (LRS) or the high-resistance state (HRS) (step S102). For example, the control circuit 20 generates logic 1 in a case where the variable resistor VR is in the low-resistance state (LRS), or generates logic 0 in a case where the variable resistor VR is in the high-resistance state (HRS), to thereby generate read data. For example, the control circuit 20 outputs the generated read data to the memory controller 300.

For example, when the absolute value of the voltage of the word line WL is greater than the absolute value of the reference voltage Vref (for example, about −1 V) as illustrated in FIG. 10, the control circuit 20 determines that the variable resistor VR is in the high-resistance state (HRS). In a case where it has been determined that the variable resistor VR is in the high-resistance state (HRS), the control circuit 20 does not perform the reset operation (step S104). When the selector element SE is not turned on by the detection operation, the control circuit 20 stops voltage application to the memory cell MC not turned on. Thereafter, the control circuit 20 may verify that the reset is not really necessary (the read operation) on an as-needed basis (step S105).

Incidentally, the reset operation according to the present embodiment is provided with the Snap detection operation before the reset operation. Thus, a voltage to snap the memory cell MC is not applied to the semi-selected cell, and therefore, there is no possibility that the state (data) of the semi-selected cell is corrupted. Furthermore, in the reset operation according to the present embodiment, after the Snap detection operation, the reset operation is performed on only cells in each of which the selector element SE is turned on. This makes it possible to perform the reset operation with a high voltage, and therefore, it is possible to expand the range of choices for a memory material.

Subsequently, the write operation (the set operation and the reset operation) of the memory cell array unit 400 according to the present embodiment is described as compared with a comparative example. FIG. 12 (A) illustrates an example of a write operation (a set operation and a reset operation) of a memory cell array unit according to the comparative example. FIG. 12 (B) illustrates an example of the write operation (the set operation and the reset operation) of the memory cell array unit 400 according to the present embodiment.

In general, write data may have any pattern. Thus, in some cases, the set operation or the reset operation is performed on all of the plurality of memory cell array units 400; in other cases, the set operation is performed on some of the plurality of memory cell array units 400, and the reset operation is performed on the other memory cell array units 400. To reduce a writing time, the memory controller 300 simultaneously performs the set operation and the reset operation on the plurality of memory cell array units 400 on the basis of the write data.

Specifically, in accordance with the write data and address data inputted to the plurality of memory cell array units 400, the memory controller 300 performs the set operation and the reset operation. For example, on the basis of the address data inputted to the plurality of memory cell array units 400, the memory controller 300 compares the write data inputted to the plurality of memory cell array units 400 with the state of each of the memory cell array units 400 (Pre-Read in FIG. 12 (A)). On the basis of a result of the comparison, the memory controller 300 performs the set operation (control of applying a set current Iset) on each of the memory cell array units 400 requiring the set operation (set in FIG. 12 (A)). The memory controller 300 further performs the reset operation sequentially on each of the memory cell array units 400 requiring the reset operation on the basis of a predetermined unit (for example, a unit of a row) while performing the set operation (Reset in FIG. 12 (A)).

However, in such a sequence, the time (the latency) for the write operation (the set operation and the reset operation) becomes longer. It is to be noted that the latency may be reduced by omitting Pre-Read. However, in that case, there is a possibility that the state of the semi-selected cell may be corrupted, and a high voltage is not able to be applied to the cell in the reset operation.

In contrast, in the present embodiment, the Snap detection operation (DC Sense in FIG. 12 (B)) is provided before the reset operation. Thus, a voltage to snap the memory cell MC is not applied to the semi-selected cell, and therefore, there is no possibility that the state (data) of the semi-selected cell is corrupted. As a result, DC Sense in FIG. 12 (B) is able to take the role of Pre-Read in FIG. 12 (A). It is therefore possible to reduce the latency by the omission of Pre-Read in FIG. 12 (A). It is to be noted that in general, the time taken for the reset operation is shorter than the time taken for the set operation. Therefore, even in a case where DC Sense in FIG. 12 (B) is performed before the reset operation, it is possible to complete DC Sense in FIG. 12 (B) and Reset in FIG. 12 (B) within a period of time for the set operation.

Furthermore, in the present embodiment, after the Snap detection operation, the reset operation (Reset in FIG. 12 (B)) is performed on only the cell in which the selector element SE is turned on. This makes it possible to perform the reset operation with a high voltage. It is therefore possible to expand the range of choices for the memory material.

### 2. MODIFICATION EXAMPLES

### Modification Example A

In the above-described embodiment, in the reset operation, the control circuit 20 may change the resistance value of the internal resistance 63 or the internal resistance 82 in accordance with the position of the memory cell MC turned on. At this time, the internal resistances 63 and 82 each have a mechanism that changes the resistance value in accordance with a control signal from the control circuit 20. When the memory cell MC turned on is located far away from the word line driver 61, the control circuit 20 sets the resistance value of the internal resistance 63 to be lower than the resistance value at a time when the memory cell MC turned on is located near the word line driver 61. When the memory cell MC turned on is located far away from the bit line driver 81, the control circuit 20 sets the resistance value of the internal resistance 82 to be lower than the resistance value at a time when the memory cell MC turned on is located near the bit line driver 81. In this case, it is possible to uniformize the influence of an IR Drop caused by a current regardless of the position of the memory cell MC turned on.

### Modification Example B

In the above-described embodiment and its modification example, the control circuit 20 may change |Vneg2−Vread| to a higher value than usual to turn on the selector element SE of the memory cell MC in which the selector element SE is not usually turned on, and perform the reset operation on the memory cell MC turned on. In this case, it is possible to re-set the resistance value of the memory cell MC that deviates from the value the resistance value may usually take to the value the resistance value may usually take. As a result, it is possible to suppress the occurrence of a malfunction such as a read error.

The present technology is described above with reference to the embodiment; however, the present disclosure is not limited to the above-described embodiment, and various modifications are possible. It is to be noted that the effects described in the present specification are merely an example. The effects of the present disclosure are not limited to those described in the present specification. The present disclosure may have effects other than those described in the present specification.

Furthermore, for example, the present disclosure may have the following configurations.

(1) A memory module including:
a plurality of memory cell array units; and
a memory controller that controls reading of data from the plurality of memory cell array units and writing of data to the plurality of memory cell array units, in which
each of the memory cell array units includes
   a plurality of first wiring lines,
   a plurality of second wiring lines,
   a memory cell array including a memory cell, the memory cell being provided at each of points of intersection of the plurality of first wiring lines and the plurality of second wiring lines on a one-to-one basis, and
   a control unit that controls reading of data from the memory cell array and writing of data to the memory cell array on the basis of control by the memory controller,
the memory cell includes a variable resistor and a selector element, the variable resistor being a resister in which one-bit information is recorded by a high or low state of a resistance value, the selector element being serially coupled to the variable resistor,
the control unit performs, on the memory cell, a detection operation to detect a state of the memory cell, and thereafter, when the selector element is turned on by the detection operation, performs, on the memory cell turned on, a reset operation to cause the memory cell turned on to change from the low-resistance state to a high-resistance state.

(2) The memory module according to (1), in which in the detection operation, the control unit outputs, to the memory cell, a first voltage that does not allow the selector element to be turned on when the variable resistor is in the high-resistance state.

(3) The memory module according to (2), in which
in the reset operation, the control unit outputs, to the memory cell, a second voltage that allows the memory cell turned on to change from the low-resistance state to the high-resistance state, and
when a transition from the detection operation to the reset operation is made, the control unit causes a voltage outputted to the memory cell to be continuously changed from the first voltage to the second voltage.

(4) The memory module according to (2) or (3), in which the control unit performs the detection operation on a plurality of first memory cells of a plurality of the memory cells, the plurality of first memory cells being coupled to the first wiring line or the second wiring line in common with the memory cell turned on.

(5) The memory module according to any one of (1) to (4), in which when the selector element is not turned on by the detection operation, the control unit stops voltage application to the memory cell not turned on.

(6) The memory module according to any one of (1) to (5), in which the control unit includes
a first internal resistance coupled to the first wiring line,
a second internal resistance coupled to the second wiring line, and
a current control circuit that limits a current that flows through the first wiring line.

(7) The memory module according to (6), in which in the reset operation, the control unit changes a resistance value of the first internal resistance or the second internal resistance in accordance with a position of the memory cell turned on.

(8) The memory module according to (2) or (3), in which the control unit changes the first voltage to a higher value than usual to turn on the selector element of the memory cell in which the selector element is not usually turned on, and performs the reset operation on the memory cell turned on.

In a memory module according to an aspect of the present disclosure, a detection operation to detect a state of a memory cell is performed on the memory cell, and thereafter, when a selector element is turned on by the detection operation, a reset operation is performed on the memory cell turned on to cause the memory cell turned on to change from a low-resistance state to a high-resistance state. This makes it possible to prevent the reset operation from being performed on a memory cell not planned to be subjected to the reset operation. Furthermore, it is possible to perform, in a period in which a set operation is performed in one memory module, a series of the detection operation and the reset operation in another memory module. It is therefore possible to omit pre-reading before the reset operation and the set operation are performed. As a result, it is possible to reduce latency by the omission of the pre-reading. It is to be noted that the effects of the present disclosure are not necessarily limited to those described here, and may include any of the effects described in the present specification.

The present application claims the benefit of Japanese Priority Patent Application JP2021-131398 filed with the Japan Patent Office on Aug. 11, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A memory module comprising:
a plurality of memory cell array units; and
a memory controller that controls reading of data from the plurality of memory cell array units and writing of data to the plurality of memory cell array units, wherein
each of the memory cell array units includes
a plurality of first wiring lines,
a plurality of second wiring lines,
a memory cell array including a memory cell, the memory cell being provided at each of points of intersection of the plurality of first wiring lines and the plurality of second wiring lines on a one-to-one basis, and
a control unit that controls reading of data from the memory cell array and writing of data to the memory cell array on a basis of control by the memory controller,
the memory cell includes a variable resistor and a selector element, the variable resistor being a resister in which one-bit information is recorded by a high or low state of a resistance value, the selector element being serially coupled to the variable resistor,
the control unit performs, on the memory cell, a detection operation to detect a state of the memory cell, and thereafter, when the selector element is turned on by the detection operation, performs, on the memory cell turned on, a reset operation to cause the memory cell turned on to change from the low-resistance state to a high-resistance state.

2. The memory module according to claim 1, wherein in the detection operation, the control unit outputs, to the memory cell, a first voltage that does not allow the selector element to be turned on when the variable resistor is in the high-resistance state.

3. The memory module according to claim 2, wherein
in the reset operation, the control unit outputs, to the memory cell, a second voltage that allows the memory cell turned on to change from the low-resistance state to the high-resistance state, and
when a transition from the detection operation to the reset operation is made, the control unit causes a voltage outputted to the memory cell to be continuously changed from the first voltage to the second voltage.

4. The memory module according to claim 2, wherein the control unit performs the detection operation on a plurality of first memory cells of a plurality of the memory cells, the plurality of first memory cells being coupled to the first wiring line or the second wiring line in common with the memory cell turned on.

5. The memory module according to claim 1, wherein when the selector element is not turned on by the detection operation, the control unit stops voltage application to the memory cell not turned on.

6. The memory module according to claim 1, wherein
the control unit includes
a first internal resistance coupled to the first wiring line,
a second internal resistance coupled to the second wiring line, and
a current control circuit that limits a current that flows through the first wiring line.

7. The memory module according to claim 6, wherein in the reset operation, the control unit changes a resistance value of the first internal resistance or the second internal resistance in accordance with a position of the memory cell turned on.

8. The memory module according to claim 2, wherein the control unit changes the first voltage to a higher value than usual to turn on the selector element of the memory cell in which the selector element is not usually turned on, and performs the reset operation on the memory cell turned on.
